(19) United States
(12) Patent Application Publication
(10) Pub. No.: US 2012/0125682 A1
(43) Pub. Date: May 24, 2012

(54) TERMINAL BOX FOR PHOTOVOLTAIC POWER GENERATION SYSTEM

(75) Inventors: HUI-MING LU, Tu-Cheng (TW); HUI-CHUAN CHEN, Tu-Cheng (TW); CHI-CHANG LU, Tu-Cheng (TW)

(73) Assignee: HON HAI PRECISION INDUSTRY CO., LTD., Tu-Cheng (TW)

(21) Appl. No.: 12/981,434

(22) Filed: Dec. 29, 2010

(30) Foreign Application Priority Data
Nov. 22, 2010 (TW) 99222594

(51) Int. Cl. H05K 7/20

(52) U.S. Cl. 174/548

(57) ABSTRACT

A terminal box structured to be electrically connectable to a photovoltaic module. The terminal box comprises a housing molded on a heat sink to enclose a first portion of the heat sink, and leave a second portion of the heat sink not enclosed by the housing. A circuit portion of the terminal box is in thermal contact with the second portion of the heat sink, for example, through a thermal pad.

### BACKGROUND

1. Technical Field

The disclosure relates to photovoltaic power generation, and more particularly to photovoltaic (PV) junction boxes for photovoltaic power generation systems.

2. Description of Related Art

Photocells providing renewable emission-free electrical power have become increasingly popular. Residential users often install solar panels on a roof to achieve maximum efficiency of light absorption. An on-grid solar power roof system provides electrical power for home use and feeds excess power to the power grid exposed to unobstructed sunlight.

A photovoltaic (PV) power generation system comprises PV panels interconnected through cables and junction boxes. A junction box is installed on the back of a PV module and comprises bypass diodes, which generates heat when the PV module is shaded from solar radiation. An overheated diode may break the junction box.

### BRIEF DESCRIPTION OF THE DRAWINGS

FIG. 1 is a schematic view of a terminal box for photovoltaic power generation system.

FIG. 2 is an exploded, isometric view of the terminal box.

FIGS. 3a and 3b are schematic bottom views of the terminal box.

FIG. 4 is a schematic top view of an exemplary embodiment of the terminal box.

FIG. 5 is a cross-sectional view of the terminal box along a line 505 in FIG. 4.

FIGS. 6a, 6b, and 6c are schematic top views of exemplary embodiments of the terminal box.

FIG. 7 is a cross-sectional view of the terminal box along a line 505 in FIG. 6a.

FIG. 8 is a schematic top view of another exemplary embodiment of the terminal box.

FIG. 9 is a cross-sectional view of the terminal box along a line 505 in FIG. 8.

FIG. 10 is a schematic top view of another exemplary embodiment of the terminal box.

FIG. 11 is a block diagram of an exemplary embodiment of a photovoltaic terminal box.

FIG. 12 is a block diagram of an exemplary embodiment of a photovoltaic module.

FIG. 13 is a block diagram of an exemplary embodiment of a photovoltaic power generation system.

FIG. 14 is a schematic view of a thermal switch of a first embodiment of a photovoltaic terminal box, the thermal switch in an ON position.

FIG. 15 is a schematic view of a thermal switch of a first embodiment of a photovoltaic terminal box, the thermal switch in an OFF position.

FIG. 16 is a schematic view of a thermal switch of a second embodiment of a photovoltaic terminal box.

FIG. 17 is a schematic view of a thermal switch of a first embodiment of a photovoltaic terminal box.

FIG. 18 is a schematic view of a thermal switch of a fourth embodiment of a photovoltaic terminal box, the thermal switch in an ON position.

FIG. 19 is a schematic view of a thermal switch of a fourth embodiment of a photovoltaic terminal box, the thermal switch in an OFF position.

### DETAILED DESCRIPTION

Description of exemplary embodiments of terminal box boxes for photovoltaic power generation systems is given in the following paragraphs which are organized as:

### 1. System Overview

1.1 Thermal conductors of the terminal box
1.2 Electric components of the terminal box
1.3 Photovoltaic power generation system
2. Exemplary embodiments of thermal switches
2.1 First exemplary embodiment of the terminal box with mechanical thermal switches
2.2 Second exemplary embodiment of the terminal box with electrical thermal switches
2.3 Third exemplary Embodiment of the terminal box with electrical thermal switches
3. Alternative embodiments
4. conclusion

### 1. System Overview

Connection described in the following refers to electrical connection by electrical conductive contacts, wiring, or metal soldering. The electrical conductive contacts may be fastened and restrained by metal screws or clamps. Photovoltaic cells described in the following, generate voltage signals when they are exposed to radiant energy and may be made from monocrystalline silicon, polycrystalline silicon, microcrystalline silicon, cadmium telluride (CdTe), copper indium selenide/sulfide (CIS), copper indium gallium (di) selenide (CIGS), or other materials.

### 1.1 Thermal Conductors of the Terminal Box

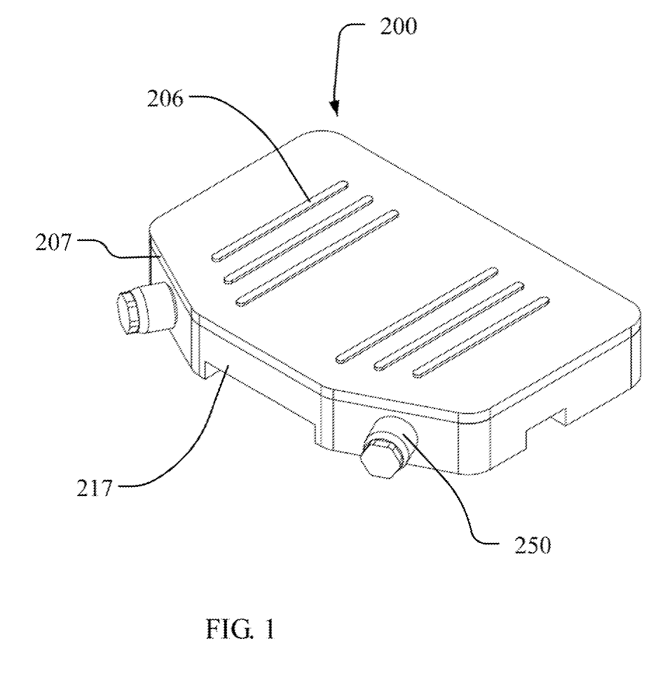

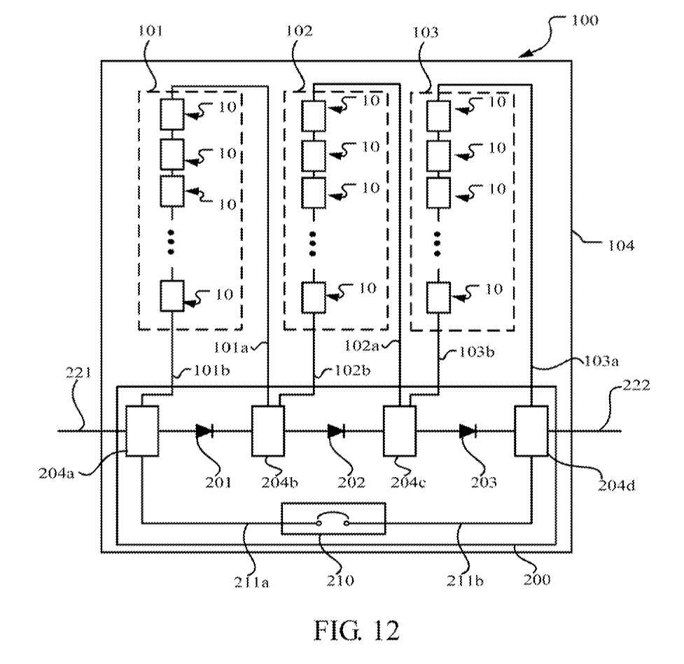

With reference to FIG. 1, a terminal box (or junction box) 200 is structured to be installed on a back surface of a photovoltaic module, such as a photovoltaic module 100 in FIG. 12. The photovoltaic module 100 comprises a solar panel. A front plane surface of the photovoltaic module 100 is the front side of the solar panel comprising solar cells and structured to receive solar radiation. The back surface of the photovoltaic module 100 is on the other side of the solar panel opposed to the front surface.

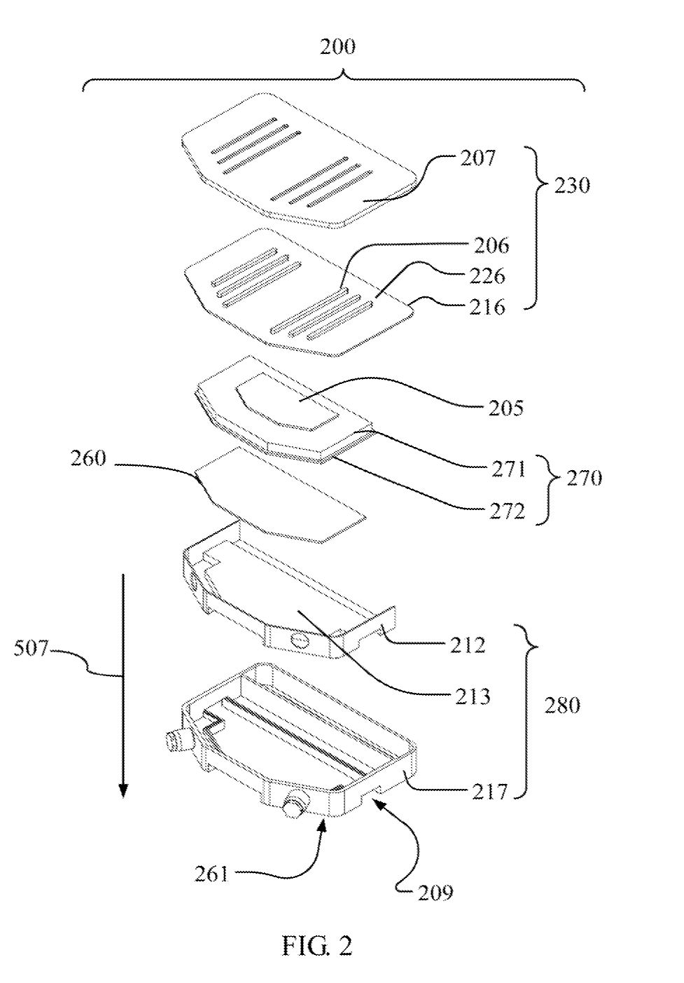

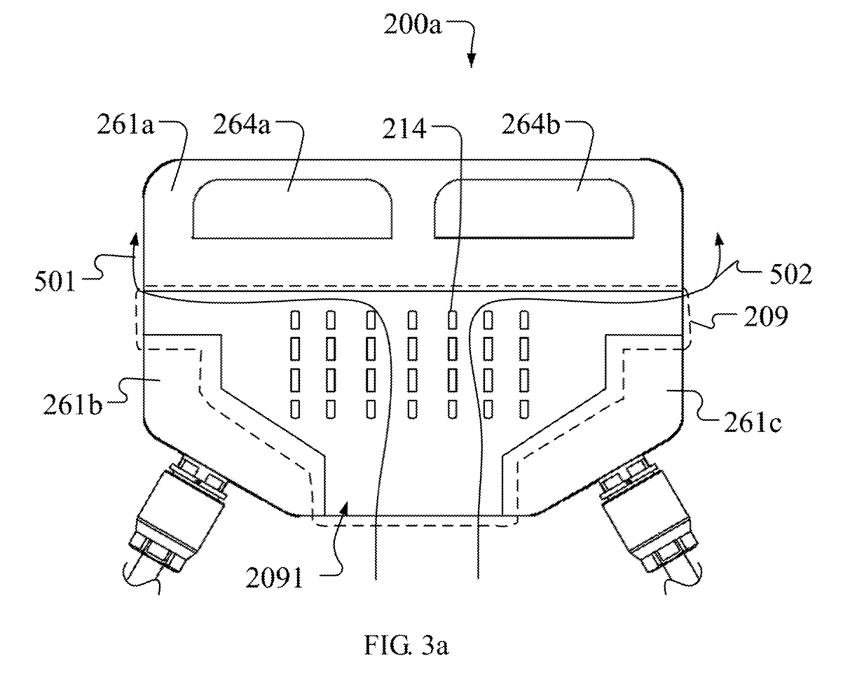

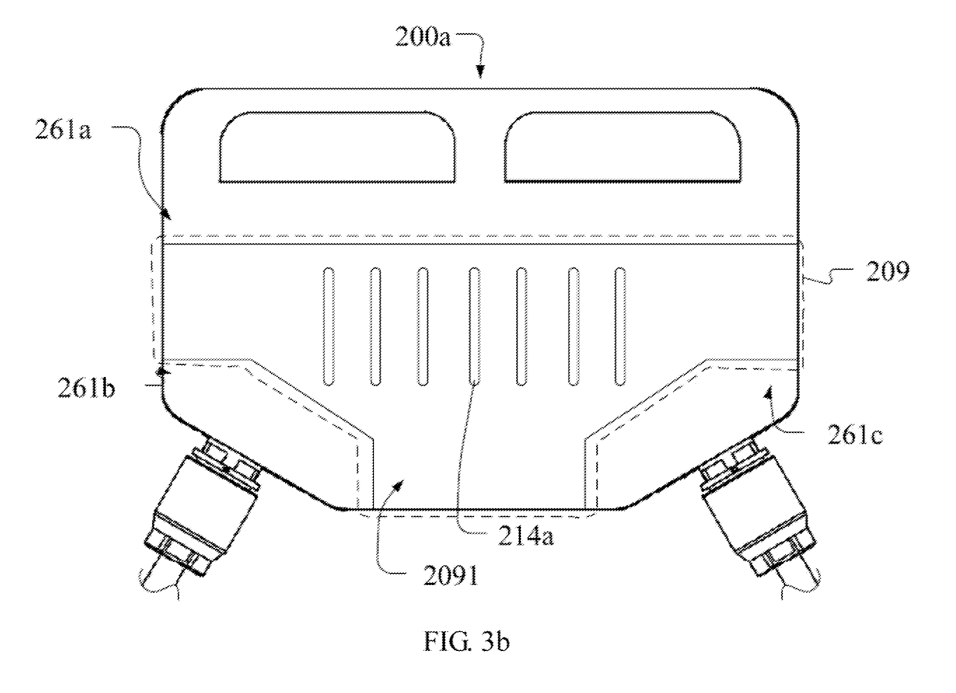

With reference to FIG. 2, the terminal box 200 comprises a first external heat sink 212, which may be, for example, made from metal or heat conductors. A housing 217 is molded on the first external heat sink 212 to enclose a first portion of the first external heat sink 212, and leave a second portion of the first external heat sink 212 not enclosed by the housing 217. The second portion of the first external heat sink 212 not enclosed by the housing 217 comprises a plane surface 213 and a fin structure opposed to the plane surface 213. The housing 217 and the first external heat sink 212 are assembled as a base 280 of the terminal box 200 with a first surface 261 structured to be attachable to the back surface of the photovoltaic module 100 along a direction 507. With reference to FIGS. 1 and 3a, a terminal box 200a is an exemplary embodiment of the terminal box 200. The first surface 261 comprises areas 261a, 261b, and 261c. A recess 209 is formed on the first surface 261. A fin structure 214 is formed on recess 209, and fins of the fin structure 214 are extended from the surface 2091 of the recess 209 along the direction 507. The recess 209 is structured to direct air to flow along paths 501 and 502. FIG. 3b shows another exemplary embodiment of a fin structure 214a. The surface 2091 may be substantially parallel with a plane of the areas 261a, 261b, and 261c.

A first thermal pad 260 is disposed on the plane surface 213 of the first external heat sink 212 in the housing 217.

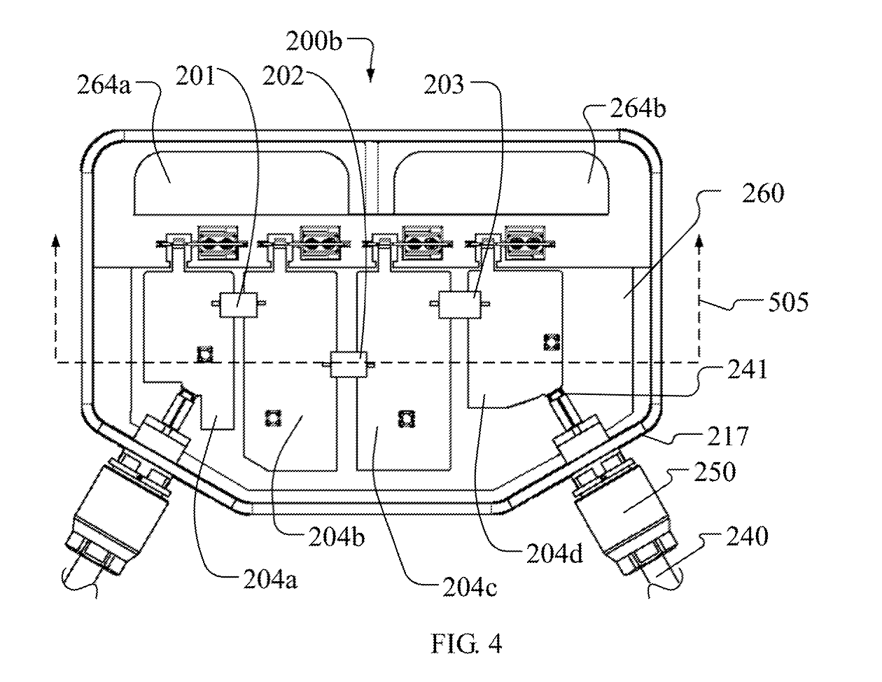

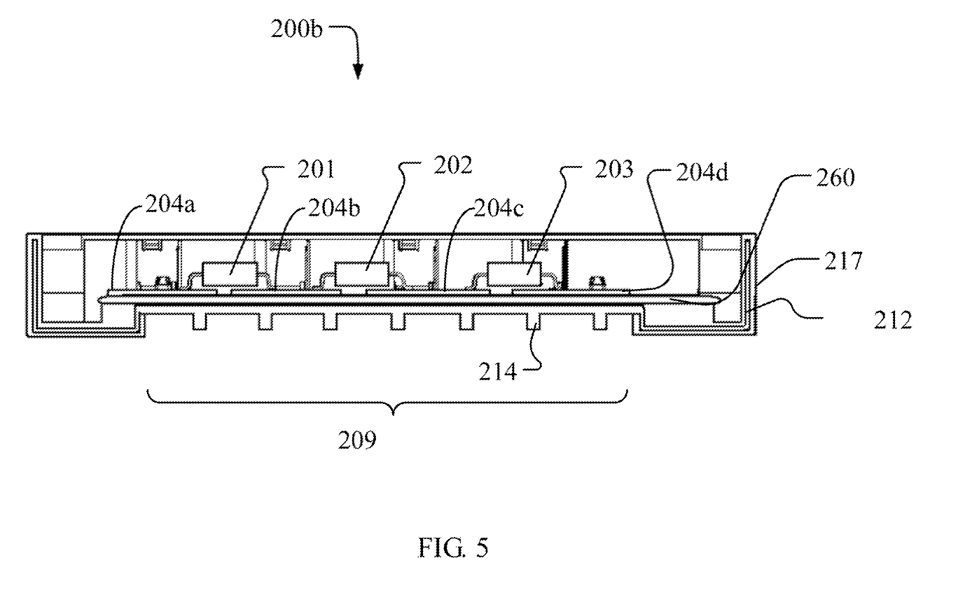

A circuit 270 operable to conduct electric signals generated by the photovoltaic module 100 is disposed on the first thermal pad 260. The circuit 270 is thus in thermal contact with the first external heat sink 212 through the first thermal pad 260. The circuit 270 comprises conductors 272 and electric components 271. For example, the circuit 270 comprises one or more bypass diodes and conductors operable to conduct electric signals generated by the photovoltaic module 100. With reference to FIGS. 4 and 5, a terminal box 200b is an exemplary embodiment of the terminal box 200. FIG. 5 is a cross sectional view of the terminal box 200b along a line 505 in FIG. 4. The circuit 270 of the terminal box 200b, for example, comprises conductive component 204a, 204b, 204c, 204d, and bypass diodes 201, 202, and 203. The conductors 272 comprise conductive component 204a, 204b, 204c, and 204d. The electric components 271 comprise bypass diodes 201, 202, and 203. The terminal box 200b comprises openings 264a and 264b. A screw 250 is utilized to fasten a cable 240 to the housing 217. The cable 240 comprises wire 241 electrically connected with conductive component 240d. The circuit 270 may comprise a thermal switch which is further detailed in the following paragraphs.

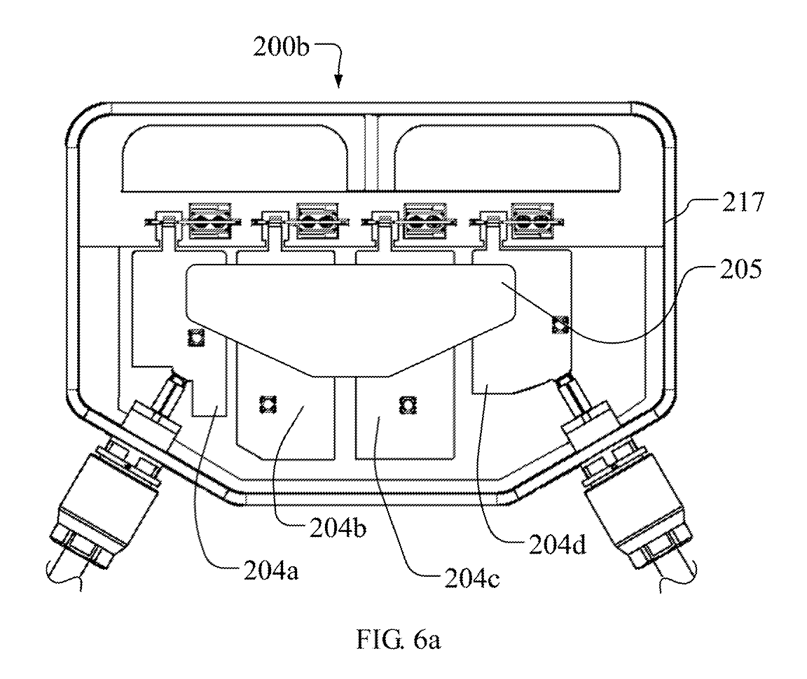

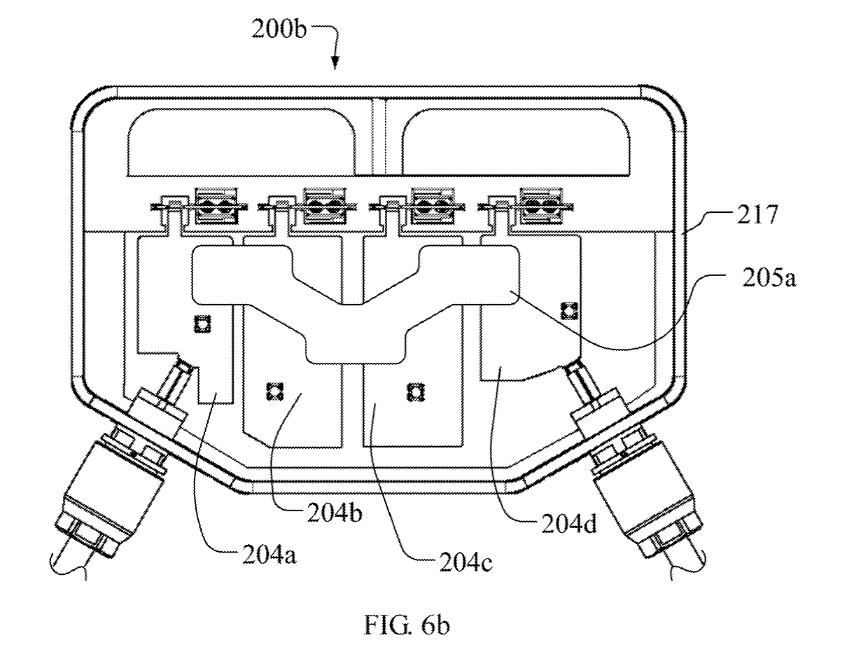

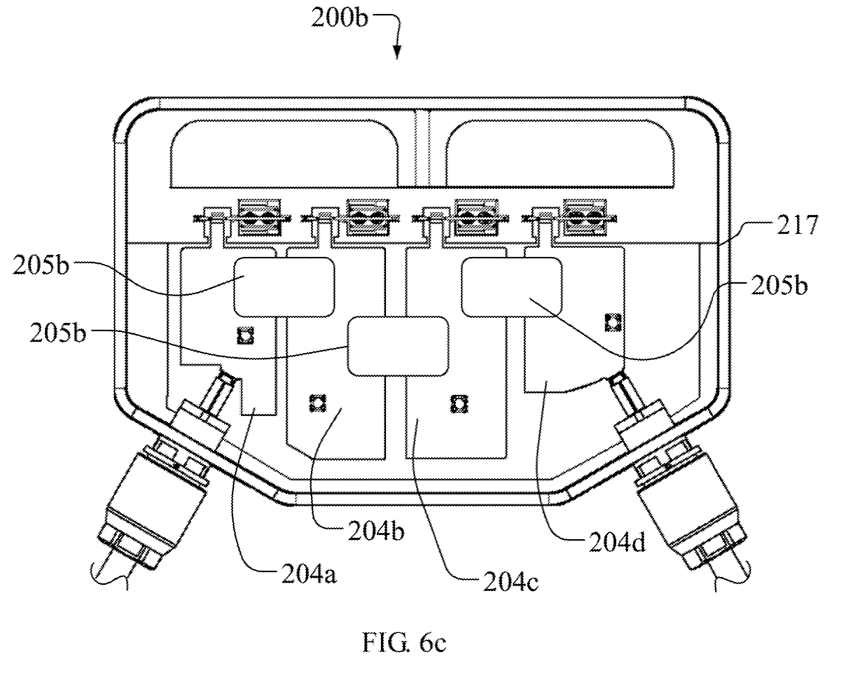

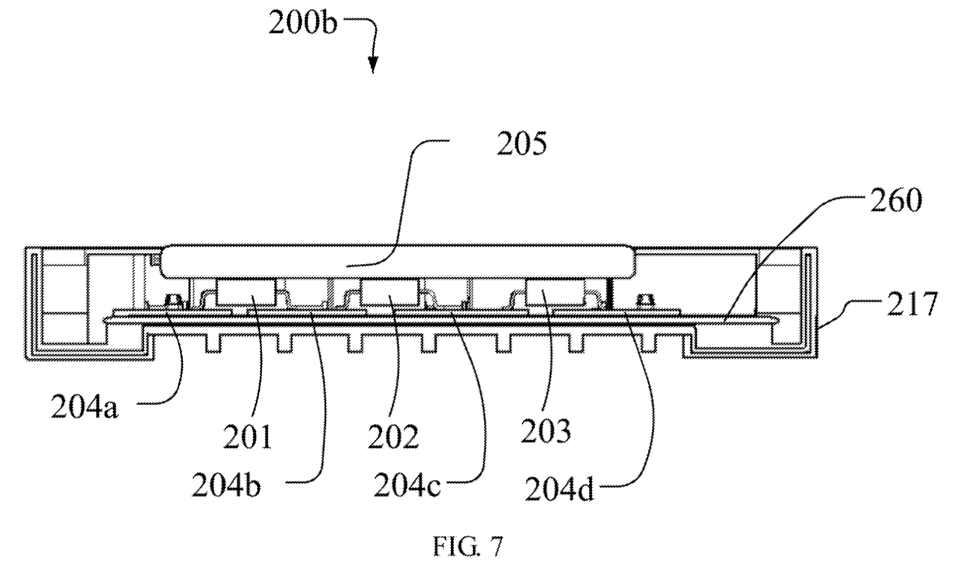

With reference to FIG. 2, a second thermal pad 205 is disposed on the circuit 270. For example, with reference to FIGS. 6a and 7, a second thermal pad 205 is disposed on the bypass diodes 201, 202, and 203. FIG. 7 is a cross sectional view of the terminal box 200b along a line 505 in FIG. 6a. FIGS. 6b and 6c shows embodiments of the second thermal pad 205, comprising 205a, and 205b.

With reference to FIG. 2, a lid 207 is molded on a second external heat sink 216 to enclose a first portion of the second external heat sink 216, and leave a second portion of the second external heat sink 216 not enclosed by the lid 207. The second portion of the second external heat sink 216 comprises fin structure 206 and a plane surface opposed to a surface 226 and fin structure 206. The plane surface of the second external heat sink 216 opposed to a surface 226 is structured to be in thermal contact with the second thermal pad 205 when the lid 207 is assembled with the base 280. The circuit 270 is thus in thermal contact with the second external heat sink 216 through the second thermal pad 205. The lid 207 and the second external heat sink 216 may be assembled as a lid assembly 230. The lid assembly 230 and the base 280 may be assembled as an the terminal box 200 by disposing the second external heat sink 216 on the second thermal pad 205, and molding the lid 207 on the second external heat sink 216 and the base 280. Alternatively, the lid 207 and the base 280 may respectively comprise latches and accordingly are assembled by these latches. The second external heat sink 216 may be made from metal or heat conductors.

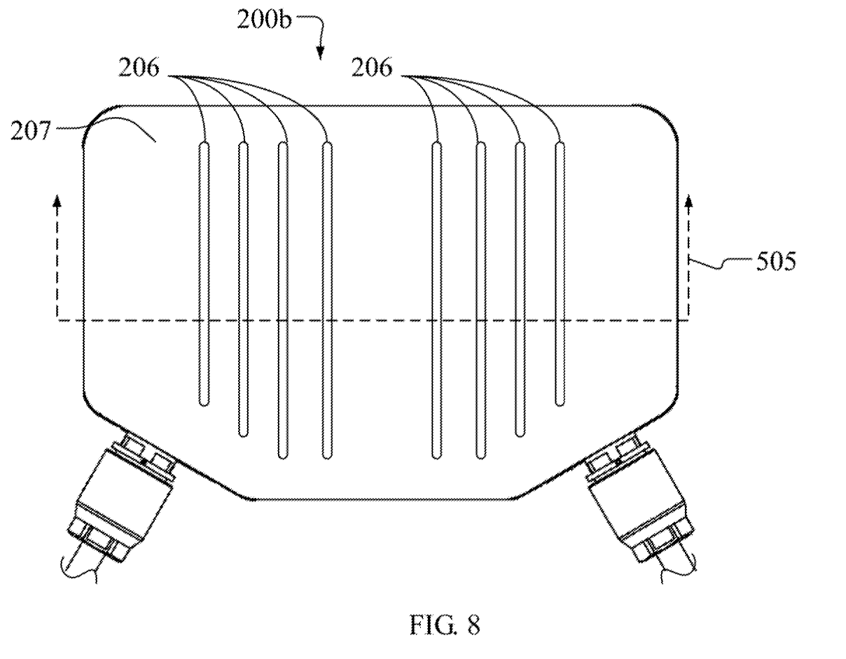

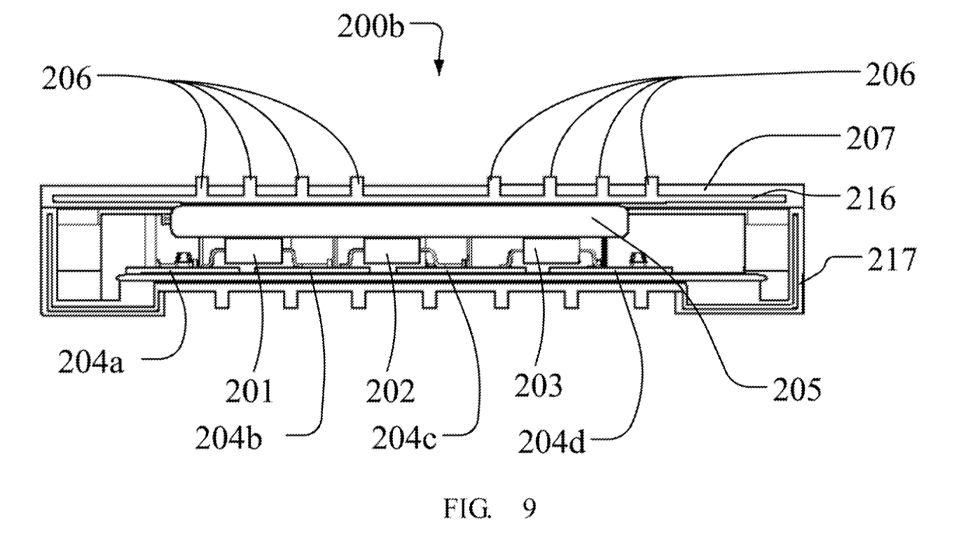

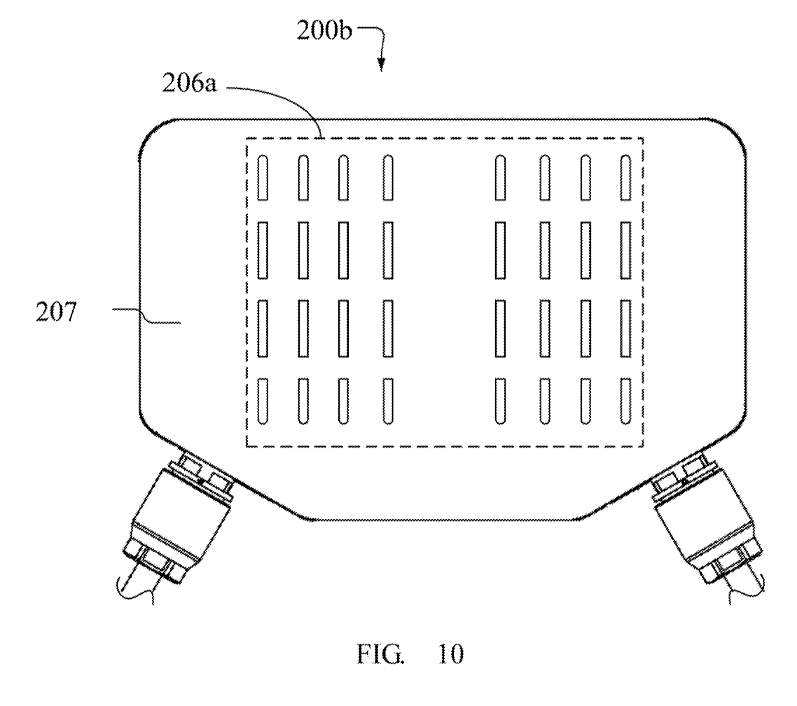

For example, with reference to FIGS. 8 and 9, the second external heat sink 216 is disposed on the second thermal pad 205, where FIG. 9 is a cross sectional view of the a terminal box 200b along a line 505 in FIG. 8. The lid 207 is molded on the second external heat sink 216 and the housing 217. Fins of the fin structure 206 extend from the surface 226 against the direction 507. FIG. 10 shows a fin structure 206a as another embodiment of the fin structure 206.

The thermal pads, such as 205, 205a, 205b, and 260 may be made from thermal conductive but electrically insulative material.

### 1.2 Electric Components of the Terminal Box

With reference to FIG. 12, the photovoltaic module 100 comprises a plurality of photovoltaic cells 10 electrically connected in series and grouped as sets 101, 102, and 103. Two output terminals of the set of photovoltaic cells provide relatively high voltage signals and low voltage signals respectively referred to as a positive terminal and a negative terminal. For example, each set of photovoltaic cells can provide about 12v across the positive and negative terminals. Positive terminals of the sets 101, 102, and 103 are operable to supply relatively high voltage signals, are respectively labeled as 101a, 102a, and 103a, and negative terminals of the sets 101, 102, and 103 are operable to supply relatively low voltage signals, are respectively labeled as 101b, 102b, and 103b. The cells 10 of the photovoltaic module 100 are attached to a first surface of a panel 104. A terminal box 200 is attached to a second surface of the panel 104 opposite to the first surface.

In the terminal box 200, the anode of bypass diode 201 is connected to a conductive component 204a, and the cathode of bypass diode 201 is connected to a conductive component 204b. Similarly, the anode and cathode of bypass diode 202 are respectively connected to conductive components 204b and 204c, and the anode and cathode of bypass diode 203 are respectively connected to conductive components 204c and 204d. Each of the conductive components 204a, 204b, 204c, and 204d may comprise a wire, a connector, an electrically conductive heat sink, or a combination thereof. Each of the bypass diodes 201-203 may raise temperature when the set of photovoltaic cells connected to the diode is shaded from solar radiation. The operating temperature of each of the bypass diodes 201-203 may be limited to less than a upper limit 120° C.

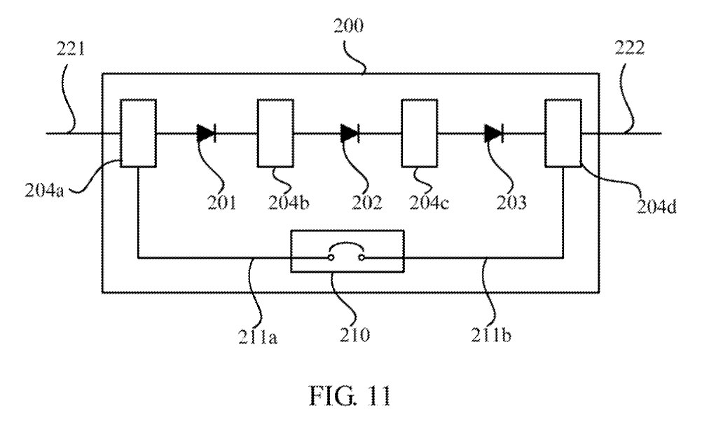

The negative terminal 101b of the set 101 is connected to the conductive component 204a, and a positive terminal 101a is connected to the conductive component 204b. Thus, the set 101 of photovoltaic cells is connected in parallel with a bypass diode 201. Similarly, as shown in FIG. 11, a negative terminal 102b and a positive terminal 102a of the set 102 are respectively connected to the conductive components 204b and 204c, and a negative terminal 103b and a positive terminal 103a of the set 103 are respectively connected to the conductive components 204c and 204d. Thus, each of the sets 102 and 103 of photovoltaic cells is respectively connected in parallel with a bypass diode 202 and a bypass diode 203.

### 1.3 Photovoltaic Power Generation System

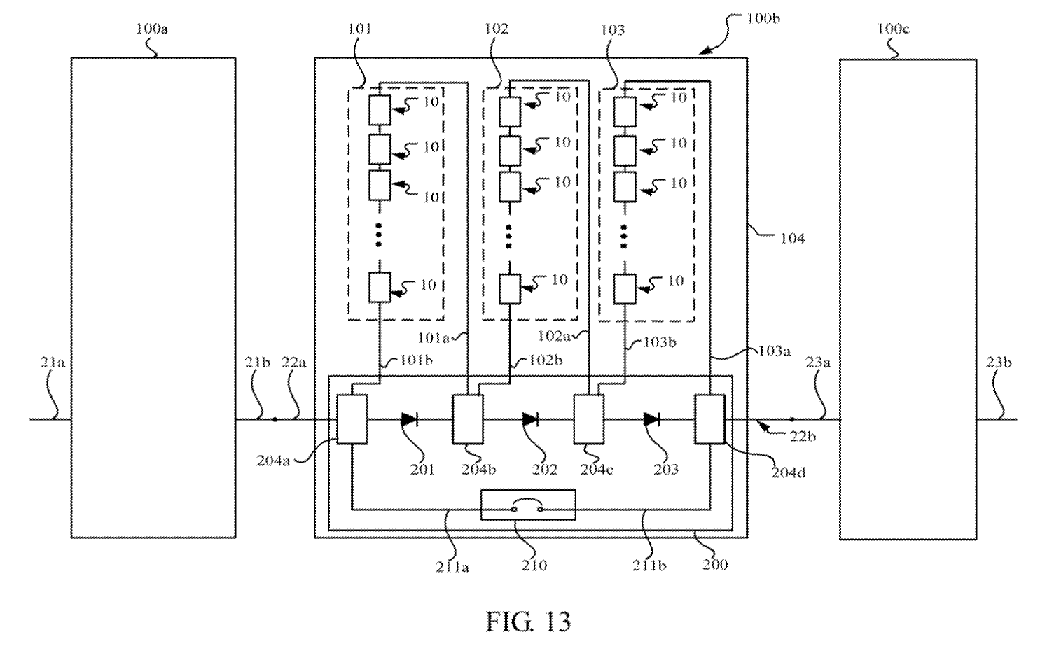

The terminal box 200 comprises two output terminals 221 and 222 electrically connectable to the photovoltaic module 100 to output voltage signals generated by the photovoltaic module 100. The photovoltaic module 100 may connect to other adjacent photovoltaic modules in parallel or in series through connectors at the ends of the output terminals 221 and 222. With reference to FIG. 13, for example, a photovoltaic power generation system comprises photovoltaic modules 100a, 100b, and 100c, each comprising an embodiment of the photovoltaic module 100. Thus, components and component connection of each of the photovoltaic module 100a, 100b, and 100c may be referred to the photovoltaic module 100. Each of the photovoltaic modules 100a and 100c may comprise the same structure and configuration as the photovoltaic modules 100b. The output terminals of terminal boxes 200 in the photovoltaic modules 100a, 100b, and 100c are respectively labeled as 21a and 21b, 22a and 22b, and 23a and 23b.

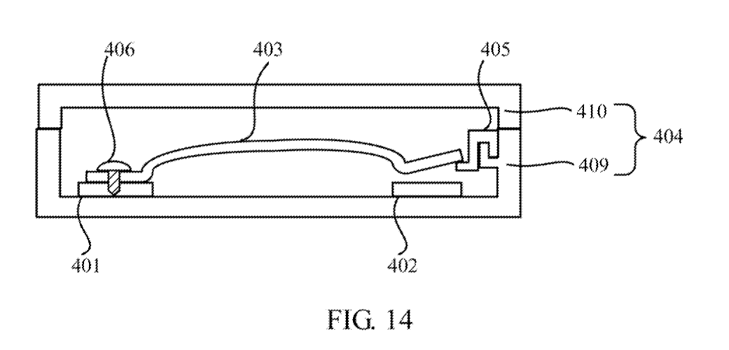

The terminal box 200 comprises a housing comprising a first surface attached to the second surface of the panel 104 of the photovoltaic module 100b. The terminal box 200 further comprises a base component and a lid facing the base component. The base component and the lid, such as bases 409 and lids 410 in FIGS. 14, 15, 18, and 19, or the housing 217 and lid 207 in FIG. 2, may be made from polymer, such as polyphenylene oxide (PPO), or polycarbonates (PC). The first surface of the housing of the terminal box 200 is formed on the base component and may be affected by operating temperature of the photovoltaic module 100b. The temperature of the first surface of the base component increases when the photovoltaic module 100b is exposed to solar radiation. In one example, the temperature of a photovoltaic module is under 800 watt/m² irradiance and 1 m/s wind velocity is typically lower than 45° C. A shaded cell in an operating photovoltaic module, such as 100b, referred to as a hot spot becomes reverse biased and dissipates power in the form of heat. A hot spot may reach 90° C. in a normal photovoltaic module and in the worst case, for example due to cell damage, may reach 150° C. to surpass critical temperature of cell encapsulants of the photovoltaic modules 100a, 100b, and 100c. Thus, the upper limit of operating temperature of the photovoltaic module 100b can be set to be lower than 150° C., such as an upper limit of about 148° C.

A thermal switch 210 has a terminal 211a electrically connected to the terminal 22a, and a terminal 211b electrically connected to the terminal 22b. OFF and ON positions of the thermal switch 210 respectively represent states in which the thermal switch 210 short-circuits and does not short-circuit the output terminals 22a and 22b. The photovoltaic module 100b with the thermal switch 210 in the ON position provides voltage signals through the output terminals 22a and 22b in response to radiant energy exposure. When the thermal switch 210 is in OFF position, the output terminals 22a and 22b of the photovoltaic module 100b is shorted by the thermal switch 210 in OFF position.

The thermal switch 210 may be disposed in the terminal box 200 to detect and respond to temperature of the terminal box 200. Specifically, the thermal switch 210 may be thermally coupled to a surface of the terminal box 200. For example, a temperature detection portion of the thermal switch 210 is thermally coupled to a second surface of the lid of the terminal box 200 facing the base component. When the temperature of the temperature detection portion of the thermal switch 210 raises to a threshold temperature T, the thermal switch 210 short-circuits the two output terminals 22a and 22b in response to temperature rise of the temperature detection portion, which reflects to the temperature of the second surface of the lid of the terminal box 200. Since house fires averagely reach approximately 650° C. (approximately 1200° F.), the threshold temperature T is required to be lower than 650° C. For example, the threshold temperature T is approximately 150° C. Additionally, the threshold temperature T of the thermal switch 210 in the terminal box is preset higher than upper limits of operating temperatures of the bypass diodes 201-203 and the photovoltaic module 100b, thus to prevent the thermal switch from erroneous short-circuit due to influence of the temperature rise of the photovoltaic module 100b and the bypass diodes 201-203.

Materials of and connection along the terminal 101b, the component 204a, the terminal 211a, the thermal switch 210, the terminal 211b, and the component 204d, and the terminal 103a are structured to withstand temperature of at least 650° C. For example, materials of the terminal 101b, the component 204a, the terminal 211a, the thermal switch 210, the terminal 211b, and the component 204d, and the terminal 103a comprises copper with melting point of approximately 1083° C. Connection between the terminal 101b, the component 204a, the terminal 211a, the thermal switch 210, the terminal 211b, and the component 204d, and the terminal 103a may be realized by screwing or clamping through screws or clamps made from materials with high melting point, such as copper, iron, stainless steel, nickel-chromium based alloy, and other high temperature resistive material.

### 2. Exemplary Embodiments of Thermal Switches

The thermal switch 210 may be bistable in the OFF and ON positions and require manual operations to return from the OFF position to the ON position. In other embodiments, the thermal switch 210 once switched to the OFF position may be irreversible.

### 2.1 First Embodiment of the Terminal Box with Mechanical Thermal Switches

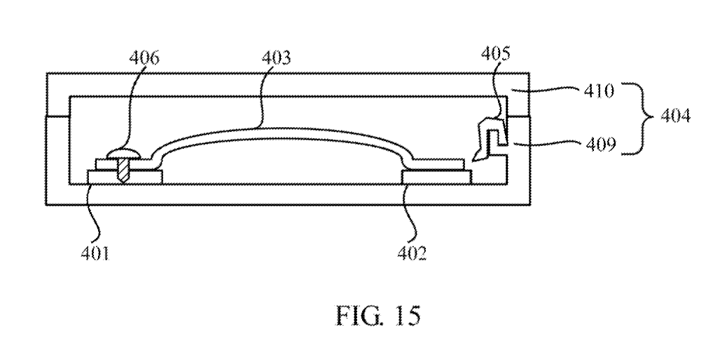

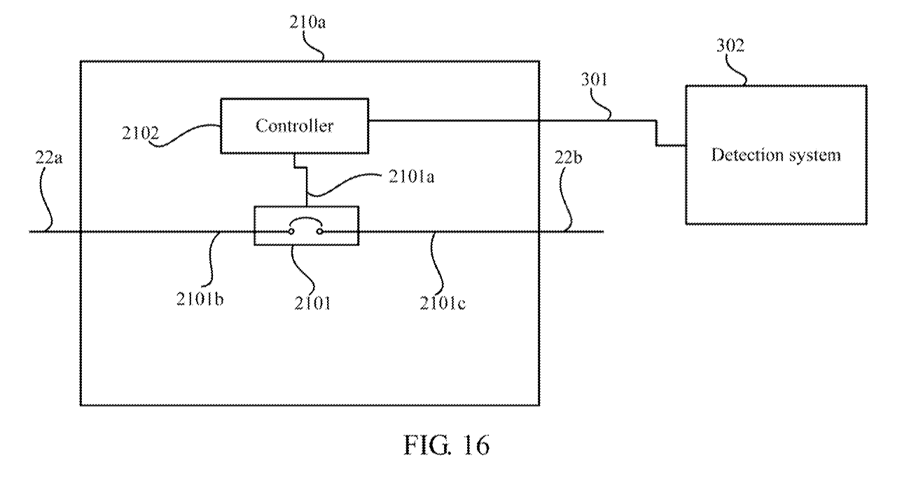

FIG. 14 is a cross section of the terminal box 200. Terminals 401 and 402 are a low voltage and a high voltage terminal of the terminal box, respectively. For example, the terminal 401 may electrically connect to or comprise the terminal 101b, 22a, component 204a, or a joint portion thereof, and the terminal 402 may electrically connect to or comprise the terminal 103a, 22b, component 204d, or a joint portion thereof. An electrically conductive component 403, such as a metal plate, is fastened on housing 404 of the terminal box 200 with the terminal 401 by a fastening component 406. The electrically conductive component 403 has flexibility to change between a forced state and a released state. As shown in FIG. 16, the electrically conductive component 403 is retained in the forced state by a fuse 405, and has mechanical strength to return to the released state when the retention force of the fuse 405 is removed. As shown in FIG. 15, the electrically conductive component 403 in the released state is electrically in contact with the terminal 402 to short circuit the terminals 401 and 402. The component 403 and the fuse 405 comprise a thermal switch 210 of a first embodiment of a photovoltaic terminal box. The fuse 405 is made up of material, such as tin alloys, or polymer, that loses strength to retain the electrically conductive component 403 in the forced state when heated to the threshold temperature T. Specifically, the fuse 405 releases the electrically conductive component 403 to the released state when heated to the threshold temperature T. For example, the melting point of the fuse 405 is designed to substantially equal the threshold temperature T. Thus, the fuse 405 comprises an exemplary embodiment of the temperature detection portion of the thermal switch 210.

Note that the distance between the terminal 402 and the component 403 in the forced state is larger than clearance distance requirement of the terminal box 200. The fuse 405 may be replaced by a bimetal operable to release the electrically conductive component 403 to the released state when heated to the threshold temperature T.

### 2.2 Second Exemplary Embodiment of the Terminal Box with Electrical Thermal Switches

With reference to FIG. 16, a switch device 210a is another example of a thermal switch 210 in a second embodiment of a photovoltaic terminal box. A switch element 2101 of the switch device 210a may comprise a mechanical or solid state switch or relay with a control terminal 2101a connected to a controller 2102. The switch element 2101 responds to the signal received from the controller 2102 through the control terminal 2101a to electrically disconnect or connect terminals 2101b and 2101c, thus to transit the switch device 210a to the ON or OFF position. The switch element 2101 may be bistable in these two states and require manual operations to return from the OFF position to the ON position. Alternatively, the switch element 2101 once switched to the OFF position may be irreversible.

The controller 2102 may comprise an electric circuit in communication with a detection system 320 through a communication channel 301. The channel 301 may comprise a wired or a wireless communication channel. The detection system 320 may comprise one or more detectors, such as a smoke detector, a thermometer, a combination thereof, or an information computer system incorporating such detectors, operable to issue an alarm signal respondent to a fire incident. The smoke detector issues the alarm signal when detecting spreading smoke. The thermometer is operable to issue the alarm signal when detecting temperature rise to a threshold value. The computer system issues the alarm signal based on data provided by at least one of the thermometer and the smoke detector, such as a density level of smoke, measured temperature, locations or identification of the thermometer and the smoke detector. The detection system 320, for example, may comprise an indoor appliance operable to issue the alarm signal in response to smoke spreading detected by the smoke detector, high temperature detected by the thermometer, or a suspected fire event determined by the computer system based on detected data. The controller 2102 may comprise an integrated circuit (IC). The controller 2102 activates the switch device 210a from the ON position to the OFF position in response to the alarm signal from the indoor system 302 respondent to a fire incident.

If channel 301 comprises a wireless communication channel, the detection system 320 may communicate with the controller 2102 through proprietary communication protocols, ZIGBEE, wireless local area network (LAN) communication, and/or cellular communication, such as wideband code division multiple access (W-CDMA) and high speed downlink packet access (HSDPA).

The controller 2102 may connect to the detection system 320 through a power inverter which converts direct current (DC) signals generated by the photovoltaic power generation system to alternating current (AC) signals. The inverter receives and transfers the alarm signal from the detection system 320 to the controller 2102. The inverter may perform signal analysis on the received alarm signal and convert the alarm signal by generating a version of the alarm signal conforming to a protocol between the inverter and the controller 2102.

### 2.3 Third Exemplary Embodiment of the Terminal Box with Electrical Thermal Switches

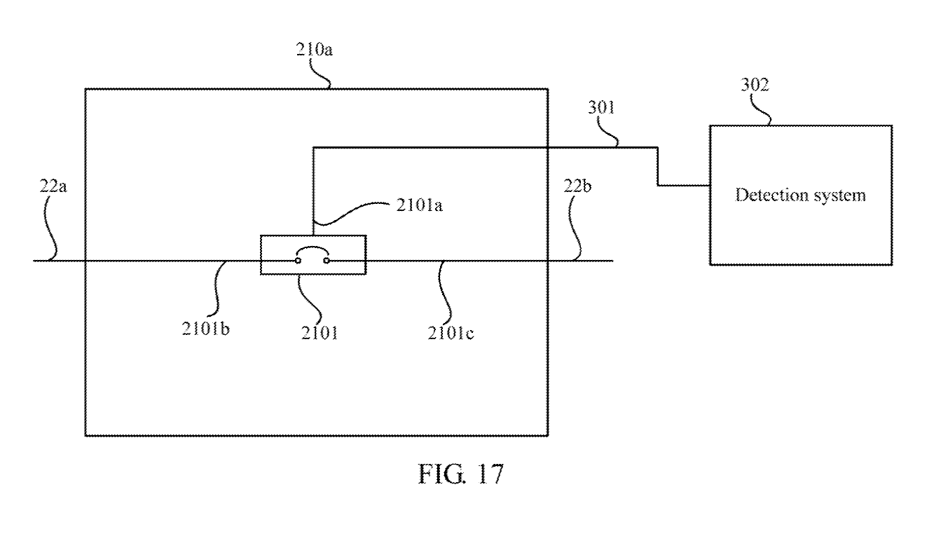

FIG. 17 shows switch device 210b of the thermal switch of a third embodiment of a photovoltaic terminal box, differing from switch device 210a only in that the detection system 320 directly energizes and controls the switch element 2101 to switch from the ON position to the OFF position through the alarm signal respondent to a fire incident.

The switch element 2101 may connect to the detection system 320 through a power inverter which converts direct current (DC) signals generated by the photovoltaic power generation system to alternating current (AC) signals. The inverter receives and transfers the alarm signal from the detection system 320 to the switch element 2101. The inverter may perform signal analysis on the received alarm signal and convert the alarm signal by generating a version of the alarm signal conforming to a protocol between the inverter and the switch element 2101.

The terminal box 200 may include at least two of the exemplary embodiments of the thermal switches in the housing thereof. The thermal switch 210 may comprise at least two of the embodiments of the thermal switches.

### 3. Alternative Embodiments

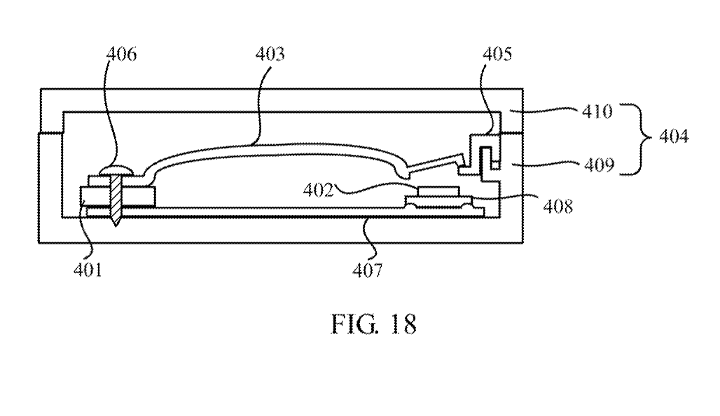

Material strength of the thermal switch 210 component 403 may be designed to retain the terminals 401 and 402 in connection even if the housing of the terminal box 200 is deformed by high temperature. With reference to FIG. 18, the thermal switch 210 further comprises components 407 and 408. The component 408 is a dielectric insulator and may be replaced by dielectric sheathing of the component 407. The components 403 and 407 comprises recesses structured to receive the terminal 402 and may be made from materials with melting point higher than 650° C., such as copper, iron, stainless steel, or nickel-chromium based alloy. The component 407 may be made from dielectric material.

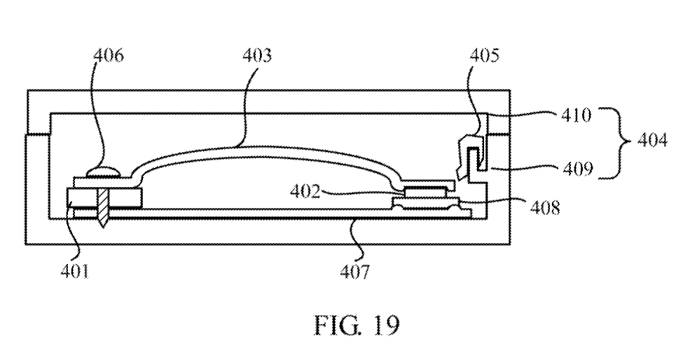

The thermal switch 210 as shown in FIG. 18 is in the ON position with the component 403 in the forced state. The thermal switch 210 as shown in FIG. 19 is in the OFF position with the component 403 in the released state. The components 403 and 407 provide retention force to hold the terminals 401 and 402 in connection in response to removal of retention force of the fuse 405. Material strength of the components 403 and 407 component 403 is designed to retain the terminals 401 and 402 in connection even if the housing of the terminal box 200 is deformed by high temperature.

### 4. Conclusion

In conclusion, the photovoltaic system terminal box is equipped with a thermal switch to reduce voltage generated by a photovoltaic module to which the photovoltaic system terminal box is attached and connected when detecting the threshold temperature T. The threshold temperature T of the thermal switch in the terminal box is preset higher than upper limits of operating temperatures of the bypass diode and the photovoltaic module, thus to prevent the thermal switch from erroneous short-circuit due to influence of the temperature rise of the photovoltaic module and the bypass diode.

It is to be understood, however, that even though numerous characteristics and advantages of the disclosure have been set forth in the foregoing description, together with details of the structure and function of the present disclosure, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A terminal box structured to be installed on a back surface of a photovoltaic module, the terminal box comprising:
a first external heat sink;
a housing molded on the first external heat sink to enclose a first portion of the first external heat sink, wherein a second portion of the first external heat sink is not enclosed by the housing, and an assembly of the housing and the first external heat sink comprises a base of the terminal box with a first surface structured to be attachable to the back surface of the photovoltaic module;
a first thermal pad disposed on the second portion of the first external heat sink in the housing; and
a circuit portion disposed on the first thermal pad, operable to conduct electric signals generated by the photovoltaic module.

2. The terminal box as claimed in claim 1, further comprising:
a second thermal pad disposed on the circuit portion;
a second external heat sink; and
a lid molded on the second external heat sink to enclose a first portion of the second external heat sink, wherein a second portion of the second external heat sink is not enclosed by the lid;
wherein the second portion of the second external heat sink is structured to be in thermal contact with the second thermal pad when the lid is assembled with the base.

3. The terminal box as claimed in claim 1, wherein the circuit portion further comprises:
a bypass diode structured to be electrically connectable to a set of photovoltaic cells in the photovoltaic module;
a first conductor structured to be electrically connected with the anode of the bypass diode; and
a second conductor structured to be electrically connected with the cathode of the bypass diode.

4. The terminal box as claimed in claim 3, wherein the second portion of the first external heat sink comprises a fin structure, and the first surface of the base comprises a recess from which the fin structure extends.

5. The terminal box as claimed in claim 1, wherein the circuit portion further comprises:
a thermal switch operable to detect temperature rise of the terminal box to a threshold temperature and reduce voltage generated by a photovoltaic module in response to the temperature rise of the terminal box to the threshold temperature.
